(19) United States
(12) Patent Application Publication
(10) Pub. No.: US 2002/0121241 A1
(43) Pub. Date: Sep. 5, 2002

(54) Processing chamber and method of distributing process fluids therein to facilitate sequential deposition of films

(76) Inventors: Anh N. Nguyen, Milpitas, CA (US); Michael X. Yang, Palo Alto, CA (US); Ming Xi, Milpitas, CA (US); Hua Chung, San Jose, CA (US); Anzhong Chang, San Jose, CA (US); Xiaoxiong Yuan, Cupertino, CA (US); Siqing Lu, San Jose, CA (US)

Correspondence Address: Applied Materials, Inc, Patent Counsel, Legal Affairs Department, P.O. Box 450 A, Santa Clara, CA, 95052, US

(21) Appl. No.: 09/798,258

(22) Filed: Mar. 2, 2001

(51) Int. Cl. C23C 16/00

(52) U.S. Cl. 118/715; 118/666; 118/663; 118/723 ME

(57) ABSTRACT

A semiconductor system includes a body defining a processing chamber, a holder disposed within the processing chamber to support the substrate, and a fluid injection assembly to facilitate sequential deposition of films. In one embodiment, the fluid injection assembly is coupled to the body and includes high-flow-velocity valves, a baffle plate, and a support. The support is connected between the valves and the baffle plate. In one embodiment the valves are coupled to the support through a W-seal to direct a flow of fluid into the processing chamber, with the flow of fluid having an original direction and a velocity associated therewith. The baffle plate is disposed in the flow path to disperse the flow of fluids in a plane extending transversely to the original direction. In this manner, the baffle plate varies the velocity of the flow of fluids.

### BACKGROUND OF THE INVENTION

1. Field of the Invention

This invention relates to semiconductor processing. More particularly, this invention relates to a processing system and method of distributing fluid therein to facilitate sequential deposition of films on a substrate.

2. Description of the Related Art

The semiconductor processing industry continues to strive for larger production yields while increasing the uniformity of layers deposited on substrates having increasingly larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer. Chemical Vapor Deposition (CVD) is a common deposition processes employed for depositing layers on a substrate. CVD is a flux-dependent deposition technique that requires precise control of the substrate temperature and precursors introduced into the processing chamber in order to produce a desired layer of uniform thickness. These requirements become more critical as substrate size increases, creating a need for more complexity in chamber design and fluid flow technique to maintain adequate uniformity.

A variant of CVD that demonstrates superior step coverage is a sequential deposition technique known as Atomic Layer Deposition (ALD). ALD has steps of chemisorption that deposit monolayers of reactive precursor molecules on a substrate surface. To that end, a pulse of a first reactive precursor is introduced into a processing chamber to deposit a first monolayer of molecules on a substrate disposed in the processing chamber. A pulse of a second reactive precursor is introduced into the processing chamber to form an additional monolayer of molecules adjacent to the first monolayer of molecules. In this manner, a layer is formed on a substrate by alternatingly pulsing an appropriate reactive precursor into a deposition chamber. Each injection of a reactive precursor is separated by an inert fluid purge to provide a new atomic layer additive to previous deposited layers to form a uniform layer on the substrate. The cycle is repeated to form the layer to a desired thickness. A drawback with ALD techniques is that the deposition rate is much lower than typical CVD techniques.

A need exists, therefore, to reduce the time required to deposit films employing sequential deposition techniques.

### SUMMARY OF THE INVENTION

Provided is a semiconductor system an exemplary embodiment of which includes a body defining a processing chamber. A holder is disposed within the processing chamber to support the substrate. A fluid injection assembly is coupled to the body. The fluid injection assembly includes high-flow-velocity valves, a baffle plate and a support. The support is connected between the valves and the baffle plate. The valves are mounted to the support to direct a flow of fluid into the processing chamber, with the flow of fluid having an original direction and a velocity associated therewith. The baffle plate is disposed in the flow path to disperse the flow of fluids in a plane extending transversely to the original direction. In this manner, the baffle plate varies both the direction and velocity of the fluid associated with the flow. A process fluid delivery system and a pressure control system are in fluid communication with the processing chamber. A temperature control system is in thermal communication therewith.

### BRIEF DESCRIPTION OF THE DRAWINGS

FIG. 1 is a simplified plan view of a plasma-based semiconductor processing system in accordance with one embodiment of the present invention;

FIG. 2 is a partial top-down view of a remote plasma source mounted to a support shown above in FIG. 1;

FIG. 3 is a cross-sectional view of the remote plasma source mounted to a support that is shown above in FIG. 2, taken along lines 3-3;

FIG. 4 is a detailed cut-away perspective view of a processing chamber shown above in FIG. 1, taken along lines 4-4;

FIG. 5 is a detailed cross-sectional view of a processing chamber, shown above in FIGS. 1 taken along lines 5-5 connected to various subsystems associated with system;

FIG. 6 is a schematic view showing deposition of a first molecule onto a substrate during sequential deposition;

FIG. 7 is a schematic view showing deposition of second molecule onto a substrate during sequential deposition to form a film layer;

FIG. 8 is a graphical representation showing the concentration of gases introduced into the processing chamber shown above in FIGS. 1, 4-5, and the relative time in which the gases are present in the processing chamber;

FIG. 9 is an exploded perspective view of a lid assembly discussed above with respect to FIGS. 1-5;

FIG. 10 is a detailed cross-section view of a portion of the lid assembly shown above in FIG. 9;

FIG. 11 is a perspective view of an alternate embodiment of a baffle plate shown above in FIG. 10;

FIG. 12 is a flow diagram showing a method to flow process fluids into the process chamber in accordance with an embodiment of the present invention;

FIG. 13 is a perspective view of a processing environment in which the processing system, shown above in FIGS. 1, 4-5, may be employed; and

FIG. 14 is a block diagram showing the hierarchical control structure of system control software employed to control the processing system, discussed above with respect to FIGS. 1, 4-5 and 13.

### DETAILED DESCRIPTION OF THE INVENTION

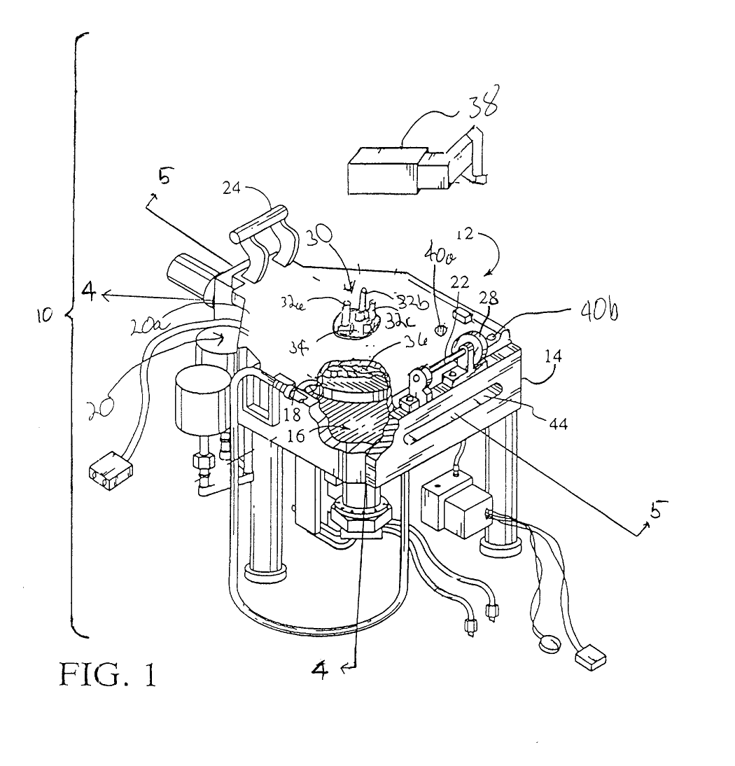

Referring to FIG. 1, a semiconductor processing system 10 in accordance with one embodiment of the present invention includes an enclosure assembly 12 formed from a process-compatible material, such as aluminum or anodized aluminum. Enclosure assembly 12 includes a housing 14, defining a processing chamber 16 with an opening 18, and a vacuum lid assembly 20. Vacuum lid assembly 20 is pivotally coupled to housing 14 via a hinge 22 to selectively cover opening 18. A handle 24 is attached to vacuum lid assembly 20, opposite to hinge 22. Handle 24 facilitates moving vacuum lid assembly 20 between opened and closed positions. In the opened position, opening 18 is exposed, allowing access to processing chamber 16. In the closed position, vacuum lid assembly 20 covers opening 18, forming a fluid-tight seal therewith. In this manner, a vacuum formed in chamber 16 maintains vacuum lid assembly 20 against housing 14. Hinge 22, however, includes a locking ratchet mechanism 28 to prevent vacuum lid assembled 20 from unintentionally moving into the closed position.

Vacuum lid assembly 20 includes a process fluid injection assembly 30 to deliver reactive and carrier fluids into processing chamber 16, discussed more fully below. To that end, fluid injection assembly 30 includes a plurality of high-flow-velocity valves, 32a, 32b and 32c, a W-seal manifold 34, a baffle plate 36 and a support 20a. Valves, 32a, 32b and 32c, W-seal manifold 34, and baffle plate 36 are mounted to support 20a, discussed more fully below.

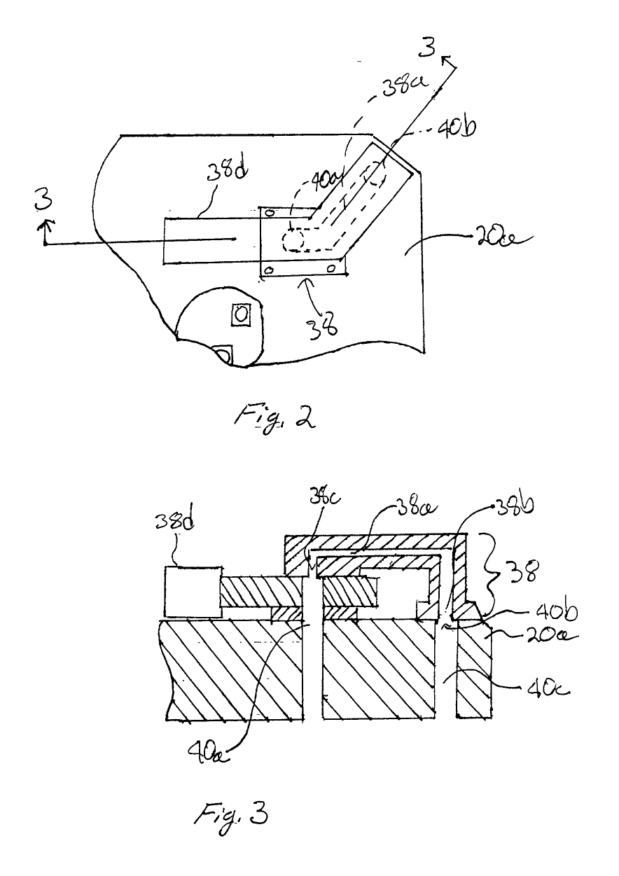

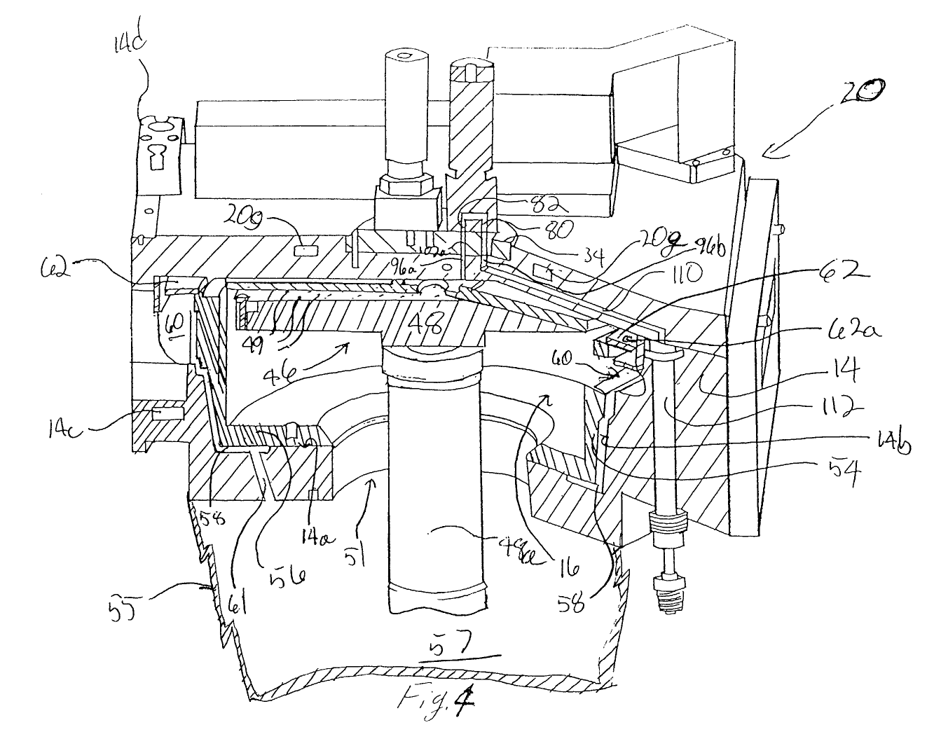

Referring to FIGS. 1, 2 and 3, attached to support 20a is a remote plasma source 38 that is placed in fluid communication with processing chamber 16 through radical input port 40a in support 20a. An intake port 40b, formed in support 20a, is in fluid communication with remote plasma source 38. Remote plasma source is a compact system that includes well-known subsystems. These subsystems include a microwave generator (not shown), in electrical communication with a plasma applicator (not shown), an autotuner (not shown), and an isolator (not shown). Wave-guides, shown for the sake of simplicity as 38a, are coupled between the aforementioned subsystems. An intake conduit 38b is in fluid communication with intake port 40b. An intake line (not shown) extends through housing 14 and is in fluid communication with intake port 40b to place a supply of etching fluids (not shown) in fluid communication with remote plasma source 38. An exit port 38c, which is in fluid communication with wave-guide 38a, is selectively placed in fluid communication with input port 40a via an isolation valve 38d.

To facilitate access to processing chamber 16, without compromising the fluid-tight seal between vacuum lid assembly 20 and housing 14, a slit valve opening 44 is present in housing 14, as well as a vacuum lock door (not shown). Slit valve opening 44 allows transfer of a wafer (not shown) between processing chamber 16 and the exterior of system 10. Any conventional wafer transfer assembly (not shown) may achieve the aforementioned transfer. An example of a conventional robotic wafer transfer assembly is described in commonly assigned U.S. Pat. No. 4,951,601 to Maydan, the complete disclosure of which is incorporated herein by reference.

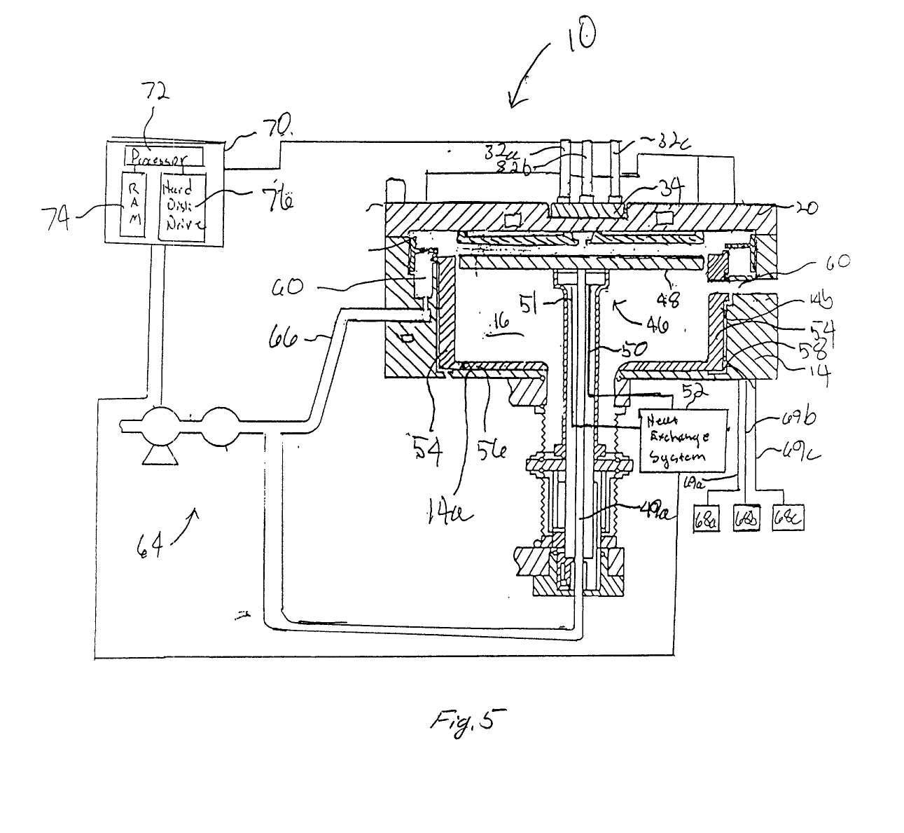

Referring to FIGS. 4 and 5, disposed within processing chamber 16 is a heater/lift assembly 46 that includes a wafer support pedestal 48 connected to a support shaft 48a. Support pedestal 48 is positioned between shaft 48a and vacuum lid assembly 20, when vacuum lid assembly 20 is in the closed position. Support shaft 48a extends from wafer support pedestal 48 away from vacuum lid assembly 20 through an orifice 51 formed in housing 14. Heater lift assembly 46 is adapted to be controllably moved so as to vary the distance between support pedestal 48 and vacuum lid assembly 20. A sensor (not shown) provides information concerning the position of support pedestal 48 within processing chamber 16. An example of a lifting mechanism for support pedestal 48 is described in detail in U.S. Pat. No. 5,951,776 to Selyutin et al., entitled “Self-Aligning Lift Mechanism”, which is assigned to the assignee of the present invention and incorporated by reference herein.

Support pedestal 48 may be maintained within a desired process temperature range employing an embedded thermocouple 50 to monitor the temperature thereof in a conventional manner. For example, the measured temperature may be used in a feedback loop to control the electrical current applied to heater element 51 by a heat exchange system 52. Optionally, support pedestal 48 may be heated using radiant heat (not shown). Support pedestal 48 may be formed from any process-compatible material, including aluminum nitride and aluminum oxide (Al₂O₃ or alumina) and may also be configured to hold a substrate thereon employing a vacuum, i.e. support pedestal 48 may be a vacuum chuck. To that end, support pedestal 48 may include a plurality of vacuum holes 49 that are placed in fluid communication with a vacuum source, such as pump system 64 via vacuum tube 49a.

A liner assembly is disposed in processing chamber 16 and includes a cylindrical portion 54 and a planar portion 56. Cylindrical portion 54 and a planar portion 56 may be formed from any suitable material such as aluminum, ceramic and the like. Cylindrical portion 54 surrounds support pedestal 48. Planar portion 56 extends transversely to cylindrical portion 54 and is disposed against a surface 14a of processing chamber 16 disposed opposite to lid assembly 20. Liner assembly defines a chamber purge channel 58 between surface housing 14 and both cylindrical portion 54 and planar portion 56. Specifically, a first portion of purge channel 58 is defined between surface 14a and planar portion 56. A second portion of purge channel 58 is defined between surface 14b and cylindrical portion 54, with surface 14b extending extends transversely to surface 14a. The second portion of chamber purge channel 58 places the first portion in fluid communication with a pump channel 60 that extends circumferentially about cylindrical portion 54 of liner assembly. Attached to a portion of housing 14 disposed opposite to lid assembly 20 is a bellows 55 forming a fluid-tight void 57, as is well known in the semiconductor processing art. Typically, void 57 is filled with an inert, or purge fluid, such as argon. Purge channel is placed in fluid communication with void 57 and, therefore, the purge fluid therein, via a through-bore 61. Through-bore 61 extends through a portion of housing 14, disposed opposite to vacuum lid assembly 20. In this manner, purge fluid in void 57 may flow through purge channel 58 to reduce, if not, prevent accumulation of residue on surfaces 14a and 14b. Accumulation of residue on support pedestal 48 and on planar portion 56 is reduced, if not prevented, by purge fluid flowing into processing chamber 16 through orifice 51.

Disposed between pump channel 60 and lid assembly 20 is a pump plate 62 that includes a plurality of apertures, one of which is shown as 62a. Pump plate 62 controls the amount of flow between processing chamber 16 and pump channel 60. The size and number and position of apertures are established to achieve uniform flow over support pedestal 48. The flow within processing chamber 16 is provided by a pump system 64. Pump system 64 is in fluid communication with processing chamber 16 via an outlet line 66 and pump channel 60. A plurality of supplies of process fluids, 68a, 68b and 68c are in fluid communication with one of valves 32a, 32b or 32c through a sequence of conduits formed in housing 14, lid assembly 20, and W-seal manifold 34, as discussed more fully below. A controller 70 regulates the operations of the various components of system 10. To that end, controller 70 includes a processor 72 in data communication with memory, such as random access memory 74 and a hard disk drive 76 and is in signal communication with pump system 64, heat exchange system 52, and valves 32a, 32b and 32b.

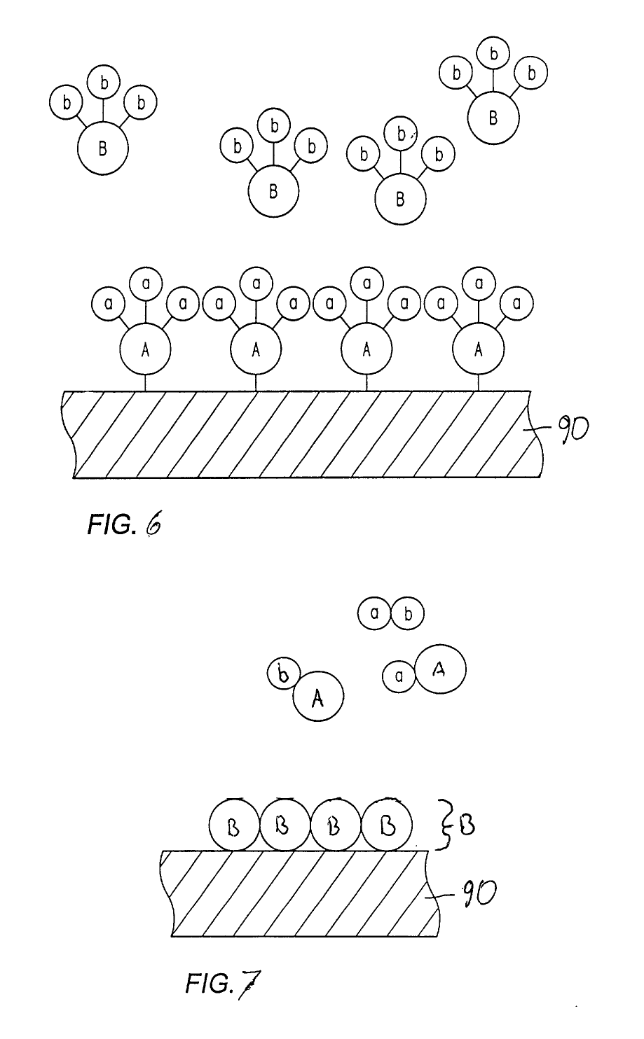

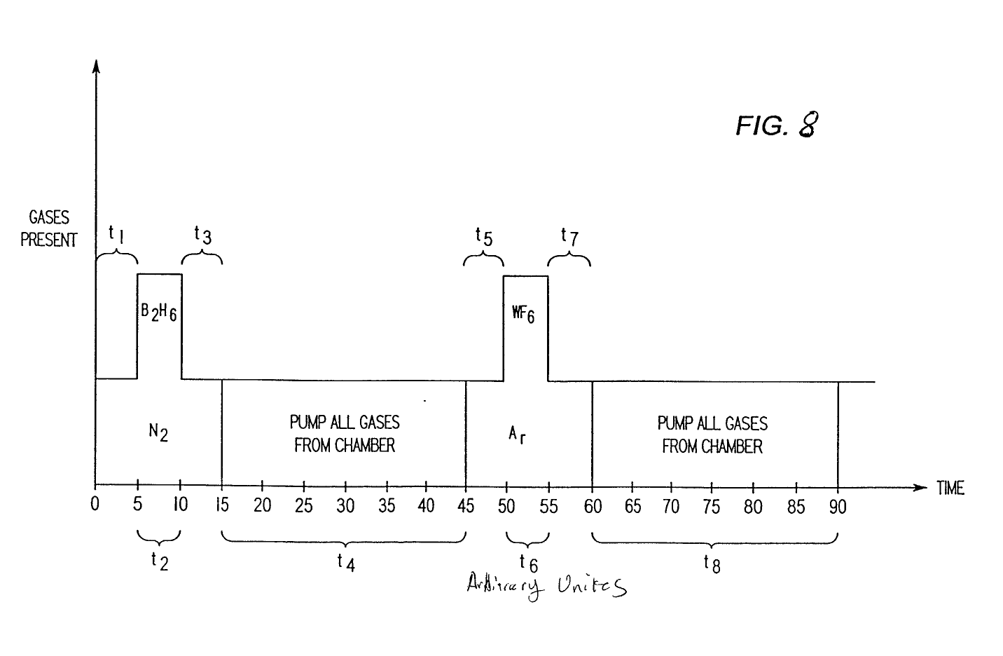

Referring to FIGS. 1, 6, and 7, during operation, system 10 deposits electrically conductive or electrically insulative layers employing sequential deposition techniques, e.g., atomic layer deposition and atomic layer nucleation. Depending on the specific stage of processing, the layers may be deposited on the material from which a substrate 90 is fabricated, e.g., SiO₂. Alternatively, the layer may be deposited on a layer previously formed on substrate 90, e.g., titanium, titanium nitride and the like. Assuming that a layer is formed on substrate 90, the initial surface presents an active ligand to the process region. A batch of a first processing fluid, in this case Aaₓ, where x is an integer, results in a layer of A being deposited on substrate 90 having a surface of ligand a exposed to processing chamber 16. Thereafter, a purge fluid enters processing chamber 16 to purge the fluid Aaₓ that remains therein. After purging Aaₓ from processing chamber 16, a second batch of processing fluid, Bb_{y}, is introduced, with y being an integer. The ligand present on substrate 90 reacts with the b ligand and B atom, releasing molecules ab, Aa and Ab, that move away from substrate 90 and are subsequently pumped from processing chamber 16. In this manner, a surface comprising a monolayer of B atoms remains upon substrate 90 and is exposed to processing chamber 16, shown in FIG. 7. The process proceeds cycle after cycle, until the desired thickness for layer B is achieved.

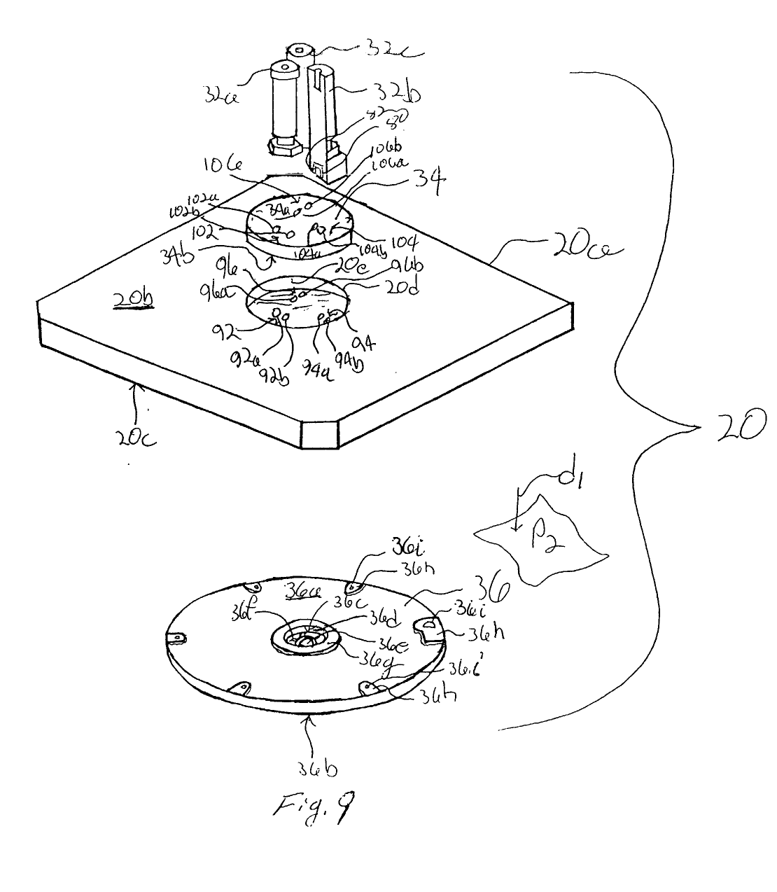

Referring to both FIGS. 4, 6, and 8, although any type of process fluid may be employed, an example is discussed in which process fluid Aaₓ is B₂H₆ gas and processing fluid Bb_{y} is WF₆ gas, and two purge fluids are employed: Ar gas and N₂ gas. The chamber pressure is in the range of 1-5 Torr, and pedestal 48 is heated in the range of 350° to 400° C. Each of the process fluids is flowed into processing chamber 16 with a carrier fluid, which in this example were one of the purge fluids: WF₆ is introduced with Ar and B₂H₆ is introduced with N₂. It should be understood, however, that the purge fluid might differ from the carrier fluid, discussed more fully below.

One cycle of the sequential deposition technique in accordance with the present invention includes flowing the purge fluid, N₂, into processing chamber 16 during time t₁, before B₂H₆ is flowed into processing chamber 16. During time t₂, the process fluid B₂H₆ is flowed into processing chamber 16 along with a carrier fluid, which in this example is N₂. After the flow of B₂H₆ terminates, the flow of N₂ continues during time t₃, purging processing chamber 16 of B₂H₆. During time t₄, processing chamber 16 is pumped so as to remove all process fluids. After pumping of processing chamber 16, the carrier fluid Ar is introduced during t₅, after which time the process fluid WF₆ is introduced into processing chamber 16, along with the carrier fluid Ar during time t₆. After the flow of WF₆ into processing chamber 16 terminates, the flow of Ar continues during time t₇. Thereafter, processing chamber 16 is pumped so as to remove all process fluids therein, during time t₈, thereby concluding one cycle of the sequential deposition technique in accordance with the present invention. This sequence of cycles is repeated until the layer being formed thereby has desired characteristics, such as thickness, conductivity and the like. It can be seen that the time required during each period t₁- t₈ greatly affects the throughput of system 10. To maximize the throughput, the lid assembly 20 and injection assembly 30 are configured to minimize the time required to inject process fluids into processing chamber 16 and disperse the fluids over the process region proximate to support pedestal 48.

Referring to FIG. 9, as discussed above, lid assembly 20 includes a support 20a, high-flow-velocity valves, 32a, 32b and 32c, W-seal manifold 34, and baffle plate 36. Valves 32a, 32b and 32c are surface mount electronically controlled valves that are available from Fujikin of Japan as part number FR-21-6.35 UGF-APD. Each of valves 32a, 32b and 32c include an input port 80 and an output port 82. Support 20a includes first and second opposed surfaces 20b and 20b, with a recessed region 20d disposed in first surface 20b. Recessed region 20d includes a sidewall 20e that extends from first surface 20b toward second surface 20b, terminating in a recessed surface 20f. Each of a plurality of pairs of fluid transfer holes 92, 94 and 96 includes a borehole, 92a, 94a and 96a that extends between recessed surface 20f and second surface 20c. Also included with each pair of fluid transfer holes 92, 94 and 96 is an inlet passage 92b, 94b and 96b.

W-seal manifold 34 is formed from a more durable material than assembly 12. For example, W-seal manifold 34 may be fabricated from stainless steel and includes a plurality of pairs of fluid transfer channels 102, 104 and 106 extending between opposed surfaces 34a and 34b. Each of the pairs of fluid transfer channels 102, 104 and 106 includes an injection channel, shown as 102a, 104a and 106a, respectively. Also included with each of the pairs of fluid transfer channels 102, 104 and 106 is a reception channel, shown as 102b, 104b and 106b, respectively.

Baffle plate 36 includes first and second opposed sides 36b and 36b. First side 36a has a recessed area 36c. Recessed area 36c includes a sidewall 36d that extends from first side 36a toward second side 36c, terminating in a nadir region that includes a throughway 36e extending between the nadir region and second surface 36b, defining an annular nadir surface 36f. An annular protrusion 36g extends from first side 36a and surrounds recessed area 36c. Spaced-apart from annular protrusion 36g are a plurality of bulwarks 36h that also extend from first side 36a. Each of the plurality of bulwarks includes a through-bore 36i adapted to receive a fastener (not shown) to couple baffle plate 36 to support 20a. Similarly, W-seal manifold 34 is coupled to support 20a via fasteners (not shown) extending through bores (not shown), and valves 32a, 32b and 32c are fastened to W-seal manifold 34 in a similar manner.

Upon being attached to support 20a, W-seal manifold 34 is disposed within recessed region 20d with surface 34b resting against recessed surface 20f forming a fluid-tight seal therewith. Fluid transfer channels 102, 104 and 106 on W-seal manifold 34 are arranged to superimpose fluid transfer holes 92, 94 and 96 and have a cross-sectional area that is coextensive therewith. In this manner, transfer channels 102, 104 and 106 are coaxial with fluid transfer holes 92, 94 and 96. Output port 82 of each of valves 32a, 32b and 32c superimposes one of injection channels 102a, 104a and 106a and, therefore, one of boreholes, 92a, 94a and 96a. Output port 82 has a cross-sectional area that is coextensive with the cross-sectional area of valve 32a, 32b and 32c it superimposes. Input port 80 of each of valves 32a, 32b and 32c superimposes one of reception channels 102a, 104a and 106a and, therefore, one of an inlet passage 92b, 94b and 96b. Input port 80 has a cross-sectional area that is coextensive with the cross-sectional area of valves 32a, 32b and 32c it superimposes. Each of injection channels 92a, 94a and 96a superimposes with annular nadir surface 36f.

Referring to FIGS. 4, 5, and 9, each of inlet passages 92b, 94b and 96b is in fluid communication with supplies of process fluids 68a, 68b and 68c via a fluid transfer channel that extends through support 20a, and a fluid feed-through that extends through housing 14. As shown, inlet passage 96b is in fluid communication with fluid transfer channel 110. Fluid transfer channel 110 is connected to fluid feed-through 112. Although not shown, fluid feed-through 112 is in fluid communication with one of supplies 68a, 68b and 68c through one of supply lines 69a, 69b and 69c, respectively. In this fashion, fluid transfer channel 110, and fluid feed-through 112 define a fluid input path. It should be understood that each of inlet passages 92b, 94b and 96b are connected to an input path that differs from the input path connected to the remaining inlet passages 92b, 94b and 96b. In this manner, each of supplies of process fluids 68a, 68b and 68c is uniquely associated with one of valves 32a, 32b and 32c, through differing feed-throughs (not shown).

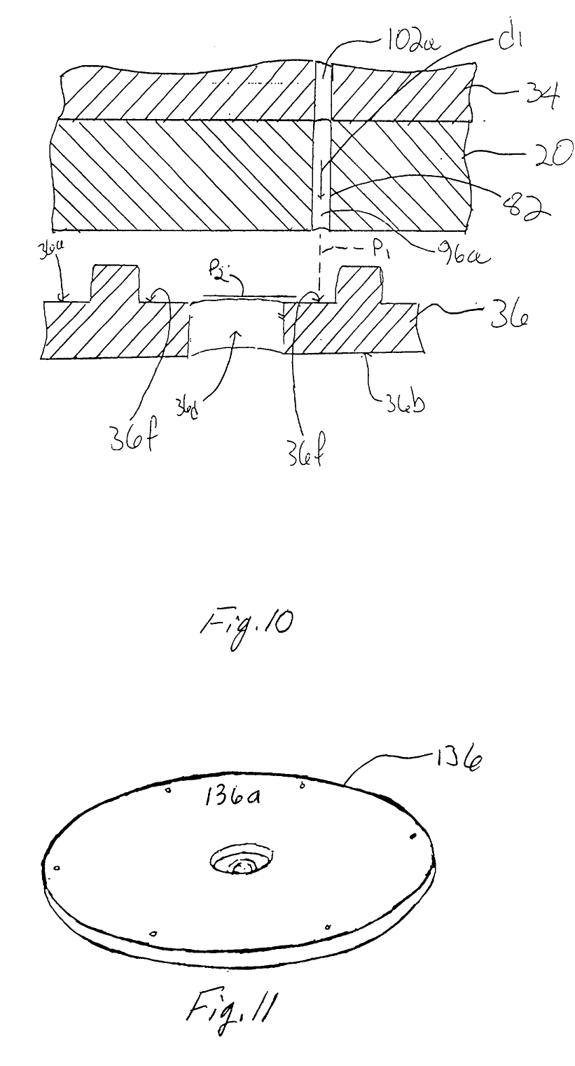

Referring to FIGS. 1, 9 and 10, a flow of process fluids into processing chamber 16 is discussed below with respect to valve 32c for ease of discussion and should be understood to apply to the two remaining valves 32a, and 32b. Lid assembly 20 is configured to minimize the time required to inject process fluids into processing chamber 16. To that end, valve 32c selectively allows fluid to flow between input port 80 and output port 82. The pressure of fluid in input port 80, before activation of valve 32c may be as high as 200 Torr, referred to as an up-stream pressure. After activation of valve 32c, fluid is transferred to output port 82 at a pressure of 200 Torr and drops rapidly, in a fraction of a second, to a pressure of as low as 2 Torr, referred to as a down-stream pressure. The difference in up-stream and down-stream pressures results in process fluids travel over path p₁ along a first direction d₁ and exiting borehole 96a at a great velocity, up to 300 meters/second. Annular nadir surface 36f reduces the velocity of the process fluids traveling through processing chamber 16, before the process fluids reach support pedestal 48. Specifically, process fluids impact with annular nadir surface 36f, and annular nadir surface 36f disperses these process fluids to travel in a plane p₂ that extends transversely to direction d₁. In this manner, the direction that the of process fluids travel is changed and the velocity of the same reduced before reaching support pedestal 48. Changing the velocity and direction of process fluids exiting borehole 96a overcomes a problem identified with implementation of valves 32a, 32b and 32b. It was found that process fluids exiting borehole 96a and passing directly through throughway 36e to impinge upon a substrate (not shown) caused a film formed on there to have non-uniform thickness. Specifically, the area of a film that is superimposed by the borehole 96a would be thinner than the remaining areas of a film. This is believed to be, in part, to a thermal gradient that is created on the substrate (not shown). The thermal gradient is believed to result in the high velocity flow of process fluids impacting upon localized regions (not shown) of the substrate (note shown). These regions (not shown) have a lower temperature than the remaining regions (not shown) of the substrate (not shown), resulting in a lower deposition in these regions (not shown). To avoid the aforementioned temperature gradient, and the aforementioned thinning effect, the process fluids are dispersed and slowed by annular nadir surface 36f. Thereafter, a pressure differential present between sides 36a and 36b causes the dispersed fluid to flow toward a common region of baffle plate 36, such as recessed region 36c. Thereafter, the process fluids once again travel along direction d₁ through throughway 36e and along path p₃.

After exiting throughway 36e, the process fluids flow away from throughway 36e and travel substantially parallel while the same impinges upon the entire area of a substrate (not shown) mounted atop of support pedestal 48. To that end, throughway 36e is radially and symmetrically disposed about an axis that is centered with respect to support pedestal 48, and the area of baffle plate 36 is substantially coextensive with the area of support pedestal 48.

Providing recessed region 20d facilitates high-speed deposition of process fluids by shortening the distance between output port 82 and baffle plate 36. Mounting of valves 32a, 32b and 32c is achieved by bolting the same to lid assembly 20. Although one embodiment of the present invention includes directly mounting valves 32a, 32b and 32c to support 20a, this configuration was found to be undesirable. Support 20a is manufactured from aluminum or other lightweight material that is unsuitable for affixing valves 32a, 32b and 32c thereto. As a result, W-seal manifold 34 is provided. W-seal manifold is manufactured from a more durable material, such as stainless steel. It was recognized that the introduction of W-seal manifold 34 increased the distance between output port 80 and baffle plate 36 by a magnitude equal, at least, to a length of injection channels 102a, 104a and 106a. Recessed region 20d is formed in support 20a to compensate for the increased distance. Specifically, W-seal manifold 34 fits within recessed region 20d, which reduces the aforementioned increase in distance between output port 80 and baffle plate 36 that results from the introduction of W-seal manifold 34.

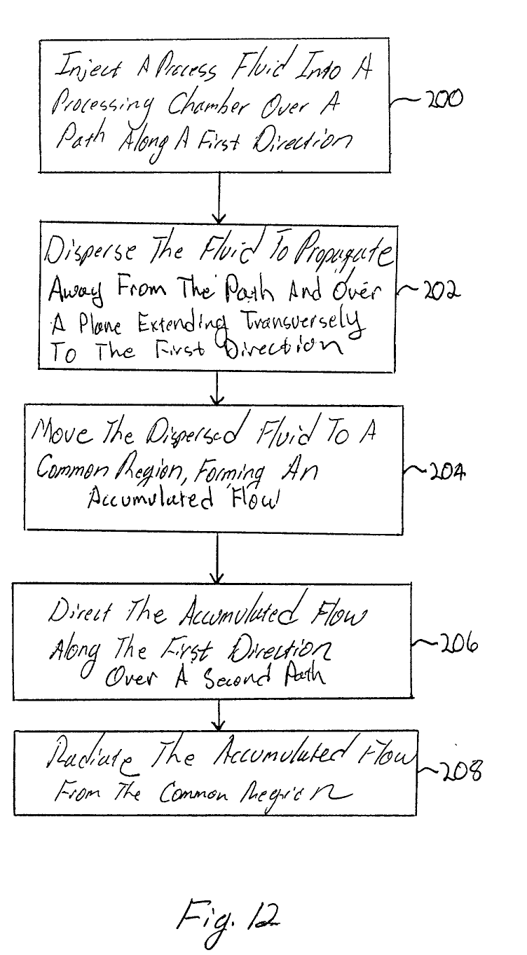

Referring to FIGS. 4, 9, and 11, another embodiment of baffle plate 36 is shown as baffle plate 136. Baffle plate 136 is identical to baffle plate 36, excepting for the omission of annular protrusion 36g and bulwarks 36h. More specifically, surface 136a is substantially planar so that the entire area thereof rests against support 20a when coupled thereto. Baffle plate 36, however, has attendant advantages by the presence of annular protrusion 36g and bulwarks 36h. With the configuration of baffle plate 36, only annular protrusion 36g and bulwarks 36h are in contact with support 20a when coupled thereto. The remaining regions of surface 36a are spaced-apart from support 20a, which facilitates removal of deposition residue from baffle plate 36 during a plasma clean process employing remote plasma source 38. This is due, it is believed, by limiting thermal conduction between baffle plate 36 and support 20a to annular protrusion 36g and bulwarks 36h. In this manner, the temperature of baffle plate 36 is maintained at a sufficiently high magnitude to remove most, if not all, residue therefrom by employing standard remote plasma clean techniques.

Further temperature control of system 10 may be achieved by coolant channels 20g in lid assembly 20 and a coolant channel 14c in housing 14, shown more clearly in FIG. 4. Coolant channels 20g and 14c are in fluid communication with a coolant manifold 14d, which is connected to a supply (not shown) of a suitable coolant.

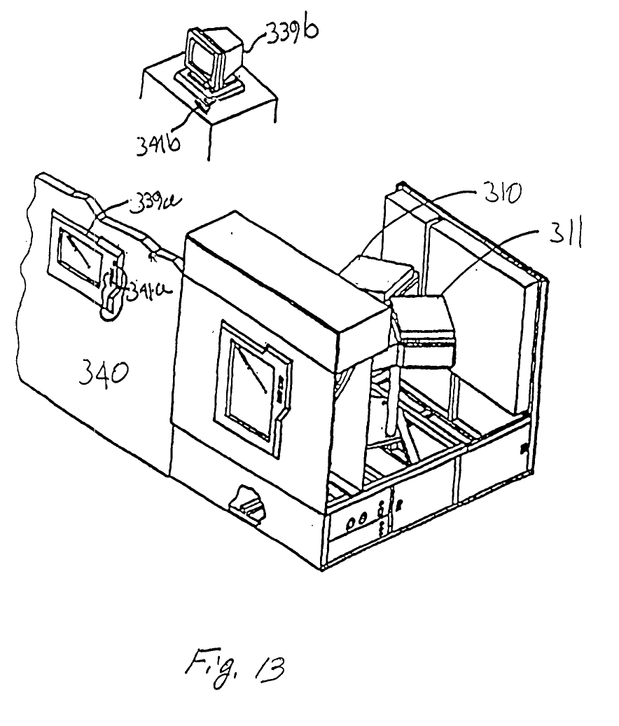

Referring to FIGS. 5, 10 and 12, an exemplary method of introducing processing fluids into semiconductor processing chamber 16 includes injecting a process fluid into said processing chamber 16 over a path p₁ in a first direction d₁ toward support pedestal 48, defining a flow of fluid at step 200. At step 202, a dispersed flow is formed from the flow of fluid by dispersing the same to propagate away from the path p₁ and over a plane p₂ that extends transversely to the first direction d₁. At step 204, the dispersed flow is moved toward a common region, such as throughway 36d, in processing chamber 16, disposed proximate to the path p₁ to form an accumulated flow of process fluid. At step 206, the accumulated flow is directed along a second path p₃, spaced-apart from the first path, along the first direction d₁. At step 208, the accumulated flow is radiated away from the common region at it travels toward support pedestal 48, shown by arrows 37.

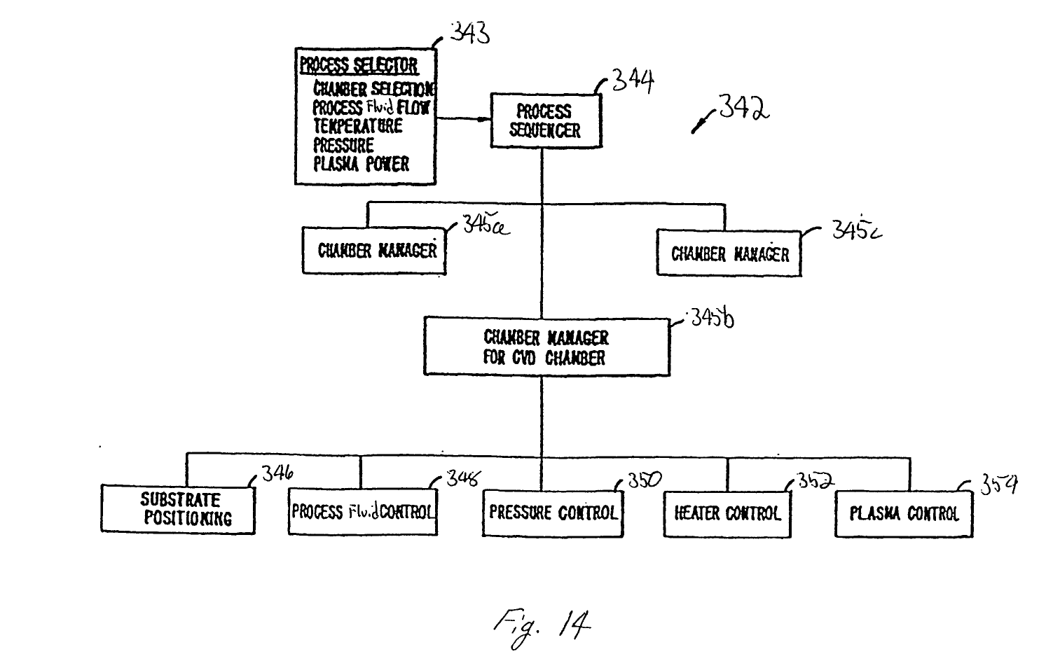

Referring to FIGS. 5 and 13 an interface between a user and controller 70 may be via a visual display. To that end, one or more monitors 339a and 339b may be employed. One monitor 339a may be mounted in a clean room wall 340 having one or more systems 310 and 311. The remaining monitor 339b may be mounted behind wall 340 for service personnel. Monitors 339a and 339b may simultaneously display the same information. Communication with controller 70 may be achieved with a light pen associated with each of monitors 339a and 139b. For example, a light pen 341a facilitates communication with controller 70 through monitor 339a, and a light pen 341b facilitates communication with controller 70 through monitor 339b. A light sensor in the tip of light pens 341a and 341b detects light emitted by CRT display in response to a user pointing the same to an area of the display screen. The touched area changes color, or a new menu or screen is displayed, confirming communication between the light pen and the display screen. Other devices, such as a keyboard, mouse, or other pointing or communication device may be used instead of or in addition to light pens 341 a and 341b to allow the user to communicate with controller 70.

As discussed above, a computer program having sets of instructions controls the various subsystems of system 10. The computer program code may be written in any conventional computer readable programming language: for example, 68000 assembly language, C, C++, Pascal, Fortran and the like. Suitable program code is entered into a single file or multiple files using a conventional text editor and stored or embodied in a computer-readable medium, such as memory 74 of controller 70. If the entered code text is a high level language, the code is compiled. The resultant compiler code is then linked with an object code of precompiled Windows® library routines. To execute the linked and compiled object code the system user invokes the object code, causing controller 70 to load the code in memory 74 from, for example, hard disk drive 76. Controller 70 then reads and executes the code to perform the tasks identified in the program.

Referring to both FIGS. 13 and 14 an illustrative block diagram of the hierarchical control stricture of the system control software is shown including a computer program 342 that a user may access using a light pen interface. For example, a user may enter a process set number and system number into a process selector subroutine 343 in response to menus or screens displayed one or more of monitors 339a and 339b. Predefined set numbers identifies the process sets, which are predetermined sets of process parameters necessary to carry out specified processes. Process selector subroutine 343 identifies (i) the desired system 310 and 311, and (ii) the desired set of process parameters needed to operate systems 310 and 311 for performing the desired process. The process parameters for performing a specific process relate to process conditions such as process fluid composition and flow rates, pressure, plasma conditions such as high- and low-frequency RF power levels and the high and low RF frequencies (and in addition, microwave generator power levels for embodiments equipped with remote microwave plasma systems), and cooling fluid pressure. Process selector subroutine 343 controls what type of process (deposition, substrate cleaning, chamber cleaning, chamber gettering, reflowing) is performed at an appropriate time. In some embodiments, there may be more than one process selector subroutine.

A process sequencer subroutine 344 comprises program code for accepting the identified system 310 and 311 and set of process parameters from chamber selector subroutine 343, and for controlling operation of systems 310 and 311. Multiple users can enter process set numbers and system numbers, or a single user can enter multiple process set numbers and system numbers, so sequencer subroutine 344 operates to schedule the selected processes in the desired sequence. Preferably, sequencer subroutine 344 includes program code to perform the steps of (i) monitoring the operation of systems 310 and 311 to determine whether systems 310 and 311 are being used, (ii) determining what processes are being carried out in systems 310 and 311, and (iii) executing the desired process based on availability of a system and the type of process to be carried out. Conventional methods of monitoring systems 310 and 311 can be used, such as polling. When scheduling the process to be executed, sequencer subroutine 344 may be designed to take into consideration the present condition of the system 310 and 311 being used in comparison with the desired process conditions for a selected process, or the “age” of each particular user-entered request, or any other relevant factor a system programmer desires to include for determining scheduling priorities.

Once sequencer subroutine 344 determines which system 310 and 311 and process set combination will be executed next, sequencer subroutine 344 initiates execution of the process set by passing the particular process set parameters to a chamber manager subroutine 345a-c that controls multiple processing tasks according to the process set determined by sequencer subroutine 344. For example, chamber manager subroutine 345b comprises program code for controlling operations in systems 310 and 311. Chamber manager subroutine 345b also controls execution of various system component subroutines that controls operation of the system components necessary to carry out the selected process set. Examples of chamber component subroutines are substrate positioning subroutine 346, process fluid control subroutine 348, pressure control subroutine 350, heater control subroutine 352, and plasma control subroutine 354. Depending on the specific configuration of the system, some embodiments include all of the above subroutines, while other embodiments may include only some of the subroutines. Those having ordinary skill in the art would readily recognize that other system control subroutines can be included depending on what processes are to be performed in systems 310 and 311. In operation, chamber manager subroutine 345b selectively schedules or calls the system component subroutines in accordance with the particular process set being executed. Chamber manager subroutine 345b schedules the system component subroutines much like sequencer subroutine 344 schedules which of systems 310 and 311 and process set is to be executed next. Typically, chamber manager subroutine 345b includes steps of monitoring the various system components, determining which components need to be operated based on the process parameters for the process set to be executed, and initiating execution of a system component subroutine responsive to the monitoring and determining steps.

Referring to both FIGS. 5 and 14, substrate positioning subroutine 346 comprises program code for controlling system components that are used to load the substrate (not shown) onto support pedestal 48 and, optionally, to lift the substrate (not shown) to a desired height in processing chamber 16 to control the spacing between the substrate (not shown) and baffle plate 36. When a substrate is loaded into processing chamber 16, heater/lift assembly 46 is lowered to receive the substrate (not shown) on support pedestal 48, and then is placed to the desired position. In operation, substrate positioning subroutine 346 controls movement of heater/lift assembly 46 and support pedestal 48 in response to process set parameters related to the support height that are transferred from chamber manager subroutine 345b.

Process fluid control subroutine 348 has program code for controlling process fluid composition and flow rates. Process fluid control subroutine 348 controls the open/close position of the safety shut-off valves (not shown), and also ramps up/down the mass flow controller (not shown) to obtain the desired fluid flow rate. Process fluid control subroutine 348 is invoked by chamber manager subroutine 345b, as are all system component subroutines, and receives subroutine process parameters related to the desired fluid flow rates from the chamber manager. Typically, process fluid control subroutine 348 operates by activating valves 32a, 32b and 32c to allow process fluids to traverse fluid supply lines 69a, 69b and 69c, without the need for either (i) reading mass flow controllers, (ii) comparing the readings to the desired flow rates or (iii) adjusting the flow rates of fluid supply lines 69a, 69b and 69c as necessary. However, process fluid control subroutine 348 includes steps for monitoring the fluid flow rates for unsafe rates, and activating the safety shut-off valves (not shown) when an unsafe condition is detected. Process fluid control subroutine 348 also controls the fluid composition and introduction of clean fluids as well as for deposition fluids, depending on the desired process (clean or deposition or other) that is selected. Alternative embodiments could have more than one process fluid control subroutine, each subroutine controlling a specific type of process or specific sets of fluid lines.

As discussed above, some processes have an inert fluid such as nitrogen, N₂, or argon, Ar, is flowed into processing chamber 16 to stabilize the pressure in processing chamber 16 before reactive process fluids are introduced. For these processes, process fluid control subroutine 348 is programmed to include steps for flowing the inert fluid into processing chamber 16 for an amount of time necessary to stabilize the pressure in processing chamber 16, and then the steps described above would be carried out. Additionally, when a process fluid is to be vaporized from a liquid precursor, process fluid control subroutine 348 would be written to include steps for bubbling a delivery fluid, such as helium, through the liquid precursor in a bubbler assembly (not shown), or for introducing a carrier fluid, such as helium, to a liquid injection system. When a bubbler is used for this type of process, process fluid control subroutine 348 regulates the flow of the delivery fluid, the pressure in the bubbler (not shown), and the bubbler temperature in order to obtain the desired process fluid flow rates. As discussed above, the desired process fluid flow rates are transferred to process fluid control subroutine 348 as process parameters. Furthermore, process fluid control subroutine 348 includes steps for obtaining the necessary delivery fluid flow rate, bubbler pressure, and bubbler temperature for the desired process fluid flow rate by accessing a stored table containing the necessary values for a given process fluid flow rate. Once the necessary values are obtained, the delivery fluid flow rate, bubbler pressure and bubbler temperature are monitored, compared to the necessary values and adjusted accordingly.

Pressure control subroutine 350 comprises program code for controlling the pressure in the processing chamber 16 by regulating, inter alia, the aperture size of the throttle valve that is included in pump system 64. The aperture size of the throttle valve is set to control the chamber pressure at a desired level in relation to the total process fluid flow, the size of processing, chamber 16, and the pumping set-point pressure for pump system 64. When pressure control subroutine 350 is invoked, the desired or target pressure level is received as a parameter from chamber manager subroutine 345b. Pressure control subroutine 350 measures the pressure in processing chamber 16 by reading one or more conventional pressure manometers connected to processing chamber 16, comparing the measure value(s) to the target pressure, obtaining PID (proportional, integral, and differential) values corresponding to the target pressure from a stored pressure table, and adjusting the throttle valve according to the PID values obtained from the pressure table. Alternatively, pressure control subroutine 350 can be written to open or close the throttle valve (not shown) to a particular aperture size to regulate the pumping capacity in processing chamber 16 to the desired level.

Heater control subroutine 352 comprises program code to control operation of heat exchange system 52 and, therefore, the temperature of heater/lift assembly 46. Plasma control subroutine 354 comprises program code to control operation of remote plasma source 38. Like the previously described system component subroutines, plasma control subroutine 354 is invoked by chamber manager subroutine 345b.

Although the invention has been described in terms of specific embodiments, one skilled in the art will recognize that various modifications may be made that are within the scope of the present invention. For example, although three valves are shown, any number of valves may be provided, depending upon the number of differing process fluids employed to deposit a film. Therefore, the scope of the invention should not be based upon the foregoing description. Rather, the scope of the invention should be determined based upon the claims recited herein, including the fall scope of equivalents thereof.

What is claimed is:

1. A semiconductor processing system for a substrate, said system comprising:
a body defining a processing chamber;
a holder, disposed within said processing chamber, to support said substrate;
a fluid injection assembly coupled to said body and including a plurality of valves;
a fluid delivery system including a plurality of supplies of process fluids, each of said plurality of valves being in fluid communication with one of said plurality of supplies of process fluids to selectively place said one of said plurality of supplies of process fluids in fluid communication with said processing chamber, with the supply of process fluids in fluid communication with one of said plurality of valves differing from the supply of process fluids in fluid communication with the remaining valves of said plurality of valves;
a temperature control system in thermal communication with said processing chamber; and
a pressure control system in fluid communication with said processing chamber.

2. The system as recited in claim 1 wherein said fluid injection assembly is connected to inject a flow of one of said process fluids into said processing chamber and reduce a velocity associated with said flow before reaching said holder and disperse said flow to move over said holder.

3. The system as recited in claim 1 wherein said fluid injection assembly further includes a baffle plate and a support connected between said plurality of valves and said baffle plate, with said plurality of valves being mounted to said support to direct a flow of process fluids into said processing chamber, with said flow of fluids having an original direction and a velocity associated therewith, said baffle plate being disposed in said flow path to disperse said flow of fluids in a plane extending transversely to said original direction and vary said velocity to have fluids associated with said flow to move across said holder.

4. The system as recited in claim 3 wherein said support includes a plurality of boreholes, each of which places one of said plurality of valves in fluid communication with said processing chamber, with said baffle plate including a throughway surrounded by a baffle region, with said baffle region superimposing said plurality of boreholes.

5. The system as recited in claim 3 wherein said support further includes first and second opposed surfaces with a borehole extending therebetween, and said baffle plate further including first and second opposed sides, with said first side having a recessed area extending from said first side, toward said second side and terminating in a nadir region having a throughway formed therein extending between said nadir region and said second side, defining an annular nadir surface, with said borehole superimposing said annular nadir surface.

6. The system as recited in claim 3 wherein said baffle plate further includes first and second opposed sides, an annular protrusion and a plurality of bulwarks spaced-apart from said annular protrusion, with said protrusion and said plurality of bulwarks extending from said first side and contacting said support, with the remaining regions of said first side being spaced-apart therefrom.

7. The system as recited in claim 3 wherein said support further includes first and second opposed surfaces and a recessed region disposed in said first surface, said recessed region including a sidewall extending from said first surface, toward said second surface and terminating in a recessed surface with a borehole extending between said recessed surface and said second surface, said baffle plate further including first and second opposed sides, with said first side having a recessed area extending from said first side, toward said second side and terminating in a nadir region having a throughway formed therein extending between said nadir region and said second side, defining an annular nadir surface, with said borehole superimposing said annular nadir surface.

8. The system as recited in claim 7 further including a W-seal manifold disposed within said recessed region, between said high-flow-velocity valve and said recessed surface, said W-seal manifold having an injection channel and a reception channel, with said injection channel being axially aligned and in fluid communication with both said output port and said borehole and having a cross-sectional area coextensive therewith, with said reception channel being in fluid communication with said input port.

9. The system as recited in claim 1 further including a W-seal manifold mounted between said injection valve and said support, said manifold having an injection channel and a reception channel, with said injection channel being axially aligned and in fluid communication with both said output port and said borehole and having a cross-sectional area coextensive therewith, with said reception channel being in fluid communication with said input port.

10. The system as recited in claim 9 wherein said processing chamber further includes an opening, with said support being coupled to said body to move between an open and closed position with said opening being sealed in said closed position, said support further including, a coolant channel and fluid conduits disposed between said first and second surfaces, with said fluid conduits in fluid communication with both said supply of process fluids and said reception channels.

11. The system as recited in claim 10 further including a remote plasma source, wherein said support further includes a radical-through-port to place said remote plasma source in fluid communication with said processing chamber, with said recessed region being centrally disposed with respect to said holder and said radical through-port being spaced-apart from said recessed region, upon said support being in said closed position.

12. A semiconductor processing system for a substrate, said system comprising:
a body defining a processing chamber having an opening;
a lid, coupled to said body to move between open and closed positions, with said opening being sealed in said open positioned and said opening being accessible in said open position;
a fluid injection assembly coupled to said lid;
a holder, disposed within said processing chamber, to support said substrate;
a fluid delivery system in fluid communication with said fluid injection assembly;
a temperature control system in thermal communication with said processing chamber; and
a pressure control system in fluid communication with said processing chamber to create a pressure differential between said lid and said holder, with said fluid injection assembly connected to inject a flow of fluids into said processing chamber and reduce a velocity associated with said flow and disperse said flow to move over said holder under force of said pressure differential.

13. The system as recited in claim 12 further including a remote plasma source coupled to said lid, with said lid having a radical-through-port to place said remote plasma source in fluid communication with said processing chamber, with said fluid injection assembly being centrally disposed with respect to said holder and said radical through-port being spaced-apart from said fluid injection assembly.

14. The system as recited in claim 12 wherein said fluid delivery system includes a plurality of supplies of process fluids, each of said plurality of valves being in fluid communication with one of said plurality of supplies of process fluids to selectively place said one of said plurality of supplies of process fluids in fluid communication with said processing chamber, with the supply of process fluids in fluid communication with one of said plurality of valves differing from the supply of process fluids in fluid communication with the remaining valves of said plurality of valves.

15. The system as recited in claim 12 wherein said lid further includes first and second opposed surfaces with a borehole extending therebetween, and said fluid injection assembly further includes a baffle plate having first and second opposed sides, with said first side having a recessed area extending from said first side and terminating in a nadir region having a throughway formed therein extending between said nadir region and said second surface, defining an annular nadir surface, with said borehole superimposing said annular nadir surface.

16. The system as recited in claim 12 wherein said fluid injection assembly further includes a W-seal manifold disposed between said plurality of valves and said lid, wherein each of said plurality of valves includes an input port and an output port and said W-seal manifold includes a plurality of pairs of fluid transfer channels, with each pair of fluid transfer channels including an injection channel and a reception channel, with each injection channel of said plurality of pairs of fluid transfer channels being axially aligned and in fluid communication with both said output port and one of said plurality of boreholes and having a cross-sectional area coextensive therewith, with said reception channel being in fluid communication with said input port.

17. The system as recited in claim 16 wherein said baffle plate further includes first and second opposed sides, an annular protrusion and a plurality of bulwarks spaced-apart from said annular protrusion, with said protrusion and said plurality of bulwarks extending from said first side and contacting said lid, with the remaining regions of said first side being spaced-apart from said lid.

18. The system as recited in claim 17 wherein said lid further includes a recessed region disposed in said first surface, said recessed region including a sidewall extending from said first surface, toward said second surface and terminating in a recessed surface with said plurality of boreholes extending between said recessed surface and said second surface, with said W-seal manifold being disposed within said recess region.

19. The system as recited in claim 18 wherein said lid further includes a coolant channel and fluid conduits, with said coolant channel and said fluid conduits being disposed between said first and second surfaces, with said fluid conduits being in fluid communication with both said fluid delivery system and said reception channels.

20. A semiconductor processing system of the type having processing chamber with a substrate holder disposed therein, said system comprising:
means for injecting a process fluid into said processing chamber over a path in a first direction toward said substrate holder, defining a flow of fluid;
means for dispersing said flow of fluid to propagate over a plane away from said path, with said plane extending transversely to said first direction, defining a dispersed flow;
means moving said dispersed flow over said plane toward a common region disposed adjacent to, and spaced-apart from, said holder, defining an accumulated flow; and
means for directing said accumulated flow along said first direction.

21. A method of introducing fluids into a semiconductor processing chamber having a substrate holder disposed therein, said method comprising:
injecting a process fluid into said processing chamber over a path in a first direction toward said substrate holder, defining a flow of fluid;
dispersing said flow of fluid to propagate over a plane away from said path, with said plane extending transversely to said first direction, defining a dispersed flow;
moving said dispersed flow over said plane toward a common region disposed adjacent to, and spaced-apart from, said holder, defining an accumulated flow; and
directing said accumulated flow along said first direction.

22. The method as recited in claim 21 wherein said common region superimposes a central area of said holder and directing said accumulated flow farther includes directing said accumulated flow toward said central area.

23. The method as recited in claim 21 wherein said flow of fluid flowing over said path has a velocity associated therewith, providing fluids in said flow with kinetic energy, with dispersing said flow of fluid occurring under force of said kinetic energy.

24. The method as recited in claim 21 wherein said chamber further includes a lid spaced-apart from said holder and moving said dispersed flow occurs under force of a pressure differential between said lid and said holder.

25. The method as recited in claim 21 wherein said chamber further includes a lid spaced-apart from said holder and moving said dispersed flow and directing said accumulated flow both occur under force of a pressure differential between said lid and said holder.

26. The method as recited in claim 21 further including dispersing said accumulated flow radially away from said common region.

27. The method as recited in claim 25 wherein dispersing said accumulated flow occurs under force of a pressure differential between said lid and said holder.

28. The method as recited in claim 21 wherein said chamber further includes a lid and further including providing a baffle plate between said lid and said holder, said baffle plate having first and second opposed sides, with said first side having a recessed area extending from said first side and terminating in a nadir region having a throughway formed therein extending between said nadir region and said second surface, defining an annular nadir surface, with dispersing said flow of fluid further including impinging said flow of fluid upon said annular nadir surface, with said region being proximate to said throughway.

29. The method as recited in claim 21 wherein said chamber includes a lid disposed opposite and spaced-apart from said holder with injecting a process fluid into said chamber further including providing a plurality of high-flow-velocity valves mounted to said lid in fluid communication with a plurality of supplies of process fluids, with each of said valves being uniquely associated with one of said plurality of supplies and activating one of said plurality of valves to inject said process fluid associated therewith.

30. A method of introducing fluids into a semiconductor processing chamber having a substrate holder disposed therein, said method comprising:
sequentially injecting a plurality of flows of process fluids into said processing chamber along a first direction toward said substrate, defining a sequence of flows;
dispersing each of said flows of said sequence to propagate over a plane away from said path, with said plane extending transversely to said first direction, defining a dispersed flow;
moving said dispersed flow over said plane toward a common region of said processing chamber disposed adjacent to, and spaced-apart from, said holder, defining an accumulated flow; and
directing said accumulated flow along said first direction.

31. The method as recited in 30 wherein said processing chamber further includes a. lid spaced-apart from said holder with sequentially injecting further including providing a plurality of high-flow-velocity valves mounted to said lid in fluid communication with a plurality of supplies of process fluids, with each of said valves being uniquely associated with one of said plurality of supplies and sequentially activating each of said plurality of valves to inject the said process fluid, from said plurality of supplies, associated therewith.

32. The method as recited in claim 31 further including creating a pressure differential between said lid and said holder wherein said region superimposes a central area of said holder and moving said accumulated flow occurs under force of said pressure differential.

33. The method as recited in claim 32 further including providing a baffle plate between said lid and said holder, said baffle plate having first and second opposed sides, with said first side having a recessed area extending from said first side and terminating in a nadir region having a throughway formed therein extending between said nadir region and said second surface, defining an annular nadir surface, with dispersing said flow of fluid further including impinging each flow of said sequence upon said annular nadir surface, with said region being proximate to said throughway.

34. The method as recited in claim 33 wherein moving said dispersed flow and directing said accumulated flow both occur under force of said pressure differential.
